(19) United States
(12) Patent Application Publication
(10) Pub. No.: US 2024/0204481 A1
(43) Pub. Date: Jun. 20, 2024

(54) SEMICONDUCTOR LASER ELEMENT

(71) Applicant: Taiwan-Asia Semiconductor Corporation, Hsinchu City (TW)

(72) Inventor: Chuan-Wei CHEN, Hsinchu City (TW)

(21) Appl. No.: 18/534,188

(22) Filed: Dec. 8, 2023

(30) Foreign Application Priority Data
Dec. 20, 2022 (TW) 111148909

(51) Int. Cl. H01S 5/06

(52) U.S. Cl. CPC H01S 5/0601; H01S 5/183

(57) ABSTRACT

A semiconductor laser element includes a semiconductor epitaxial structure, a light-absorbing structure, a transparent conductive layer, and an electrode layer. The semiconductor epitaxial structure includes a light-emitting layer and a light-emitting control layer. The light-emitting control layer forms a light-emitting opening area. The light-absorbing structure forms a hollow part to expose the semiconductor epitaxial structure. The band gap of the light-absorbing structure is smaller than the light-emitting band gap. The transparent conductive layer includes a recessed window part and an extension part. The recessed window part is located in the hollow part and covers the semiconductor epitaxial structure. The extension part covers the light absorbing structure. The electrode layer forms an opening to expose to the transparent conductive layer, and the opening of the layer, and the recessed window part is located in the opening. The position of the recessed window part corresponds to that of the light-emitting opening area.

### CROSS-REFERENCES TO RELATED APPLICATIONS

This application claims the benefit of priority to Taiwanese Patent Application No. 111148909 filed on Dec. 20, 2022, which is hereby incorporated by reference in its entirety.

### BACKGROUND OF THE INVENTION

### Field of the Invention

The present invention relates to a semiconductor laser element, in particular, to a semiconductor laser element that can improve luminous efficiency and easily control the luminous mode.

### Descriptions of the Related Art

Laser diodes have the capability of emitting strong laser-like light in a compact form, so they are widely used in various fields, such as optical transmission, medical treatment, 3D sensing, and 3C products. According to the different directions of epitaxial crystal resonance and laser light emission, laser diodes can be mainly divided into vertical-cavity surface-emitting lasers (VCSEL) and edge-emitting lasers. (edge emitting laser, referred to as EEL). Because VCSEL elements have higher optical purity and lower energy consumption than EEL elements, they have gradually become the mainstream of laser diodes in recent years.

Taking VCSEL elements with a ridge structure as an example, metal electrodes are generally formed outside the ridge, and holes are opened on the metal electrodes for light emission. Since the electrode will block the light, the position of the aforementioned hole cannot be excessively retracted. However, it is also necessary to take into account factors such as the ohmic contact area of the electrode not being too small and the alignment of the electrode position. As a result, there will be a gap between the electrode position and the light-emitting area position. Large position deviation causes current to easily accumulate at the outer edge of the light-emitting area; therefore, conventional VCSEL devices often suffer from problems such as uneven current distribution and inability to effectively control the light-emitting mode.

Therefore, how to design a semiconductor laser element that can improve the aforementioned problems is indeed a subject worthy of study.

### SUMMARY OF THE INVENTION

The main objective of the present invention is to provide a semiconductor laser element that can improve the luminous efficiency and easily control luminous modes.

To achieve the above objective, the semiconductor laser element comprises a semiconductor epitaxial structure, a light-absorbing structure, a transparent conductive layer, and an electrode layer. The semiconductor epitaxial structure includes a light-emitting layer and a light-emitting control layer, wherein the light-emitting control layer is located above the light-emitting layer and forms a light-emitting opening area. The light-absorbing structure is located on the semiconductor epitaxial structure and forms a hollow part to expose the semiconductor epitaxial structure, wherein a band gap of the light-absorbing structure is smaller than the light-emitting band gap. The transparent conductive layer includes a recessed window part and an extension part, the recessed window part is located in the hollow part and covers the semiconductor epitaxial structure, and the extension part covers the light absorbing structure. The electrode layer is located on the transparent conductive layer and forms an opening to expose the transparent conductive layer, wherein the recessed window part is located in the opening. Wherein a position of the recessed window part corresponds to a position of the light-emitting opening area based on the light-emitting direction.

In one embodiment of the present invention, the light-absorbing structure includes a first light-absorbing layer that is electrically conductive.

In one embodiment of the present invention, the light absorbing structure further includes a second light absorbing layer, the first light absorbing layer is stacked on the second light absorbing layer, and the second light absorbing layer and the first light absorbing layer have opposite polarities.

In one embodiment of the present invention, the light-absorbing structure further includes a second light-absorbing layer, the first light-absorbing layer is stacked on the second light-absorbing layer, and the second light-absorbing layer has insulating properties.

In one embodiment of the present invention, the light-absorbing structure further includes a second light-absorbing layer and a third light-absorbing layer, the first light-absorbing layer is stacked on the second light-absorbing layer, and the second light-absorbing layer is stacked on the third light-absorbing layer; wherein the second light absorbing layer and the first light absorbing layer have opposite polarities, and the third light absorbing layer and the first light absorbing layer have the same polarity.

In one embodiment of the present invention, a radial length of the opening is greater than the radial length of the recessed window part.

In one embodiment of the present invention, the radial length of the light-emitting opening area is greater than the radial length of the recessed window part, so that the semiconductor laser element provides single-mode light emission

In one embodiment of the present invention, the radial length of the light-emitting opening area is no greater than the radial length of the recessed window part, so that the semiconductor laser element provides multi-mode light emission.

In one embodiment of the present invention, the thickness of the transparent conductive layer is n*λ/4.

In one embodiment of the present invention, the recessed window part forms an ohmic contact with the semiconductor epitaxial structure.

In one embodiment of the present invention, the light-absorbing structure is made of gallium arsenide material, aluminum gallium arsenide material, or aluminum gallium indium arsenide phosphorus material.

In one embodiment of the present invention, the semiconductor epitaxial structure further includes a first semiconductor structure; and a second semiconductor structure, wherein the light-emitting layer is located between the first semiconductor structure and the second semiconductor structure, and the light-emitting control layer is formed in the second semiconductor structure adjacent to the light-emitting layer.

Accordingly, the semiconductor laser element of the present invention can form an ohmic contact with a large area above the light-emitting opening area and good conductivity through the light-absorbing structure and the arrangement of the transparent conductive layer, so that the current inside the light-emitting cavity can be evenly distributed. At the same time, by changing the radial length of the light-emitting opening area and the recessed window part of the transparent conductive layer can effectively control the light-emitting mode of the semiconductor laser element.

### BRIEF DESCRIPTION OF THE DRAWINGS

FIG. 1 is a schematic diagram of the semiconductor laser element of the first embodiment of the present invention.

FIG. 2 is a schematic diagram of the semiconductor laser element of the second embodiment of the present invention.

FIG. 3 is a schematic diagram of the semiconductor laser element of the third embodiment of the present invention.

### DETAILED DESCRIPTION OF THE PREFERRED EMBODIMENT

Since various modifications and embodiments are only illustrative and not limiting, after reading this specification, those with ordinary skill in the art may conceive of other variations and embodiments that do not depart from the scope of the present invention. The features and advantages of such embodiments will be further highlighted based on the detailed description and the scope of the claims set forth below.

In this document, the terms “one” or “a” are used to describe the components and elements disclosed herein. This is done for convenience and to provide a general meaning to the scope of the present invention. Therefore, unless otherwise explicitly indicated, such descriptions should be understood to encompass one or at least one, and the singular also includes the plural.

In this document, terms like “first” or “second” and similar ordinal numbers are primarily used to distinguish or refer to similar or analogous components or structures and do not necessarily imply an order in space or time. It should be understood that in certain situations or configurations, ordinal numbers can be used interchangeably without affecting the implementation of the present disclosure.

In this document, terms like “comprising,” “including,” “having,” or any similar expressions are intended to cover non-exclusively inclusive entities. For example, components or structures containing multiple elements are not limited solely to the listed elements in this document but may include other elements that are typically inherent to the component or structure even if not explicitly listed.

In this document, a term like “radial length” refers to the structural extension length of any structure in a direction perpendicular to the direction of light emission. When the structure is an opening, its radial length is the diameter of the opening (if the opening is a round hole, the radial length is the diameter of the opening)

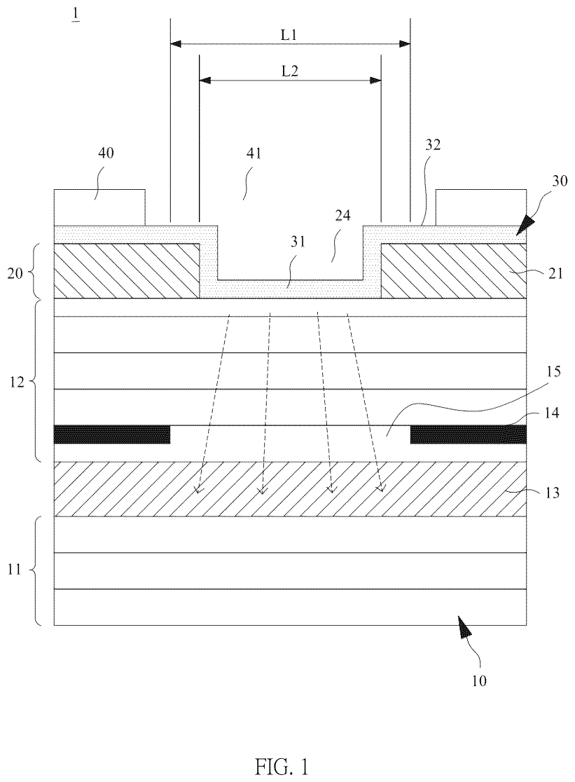

Please refer to FIG. 1 which is a schematic diagram of the first embodiment of the semiconductor laser element of the present invention. As shown in FIG. 1, the semiconductor laser element 1 of the present invention includes a semiconductor epitaxial structure 10, a light-absorbing structure 20, a transparent conductive layer 30, and an electrode layer 40. The semiconductor epitaxial structure 10 is the basic structural component of the semiconductor laser element 1 and is used as a resonant cavity of the laser. The semiconductor epitaxial structure 10 mainly includes a light-emitting layer 13 and a light-emitting control layer 14. The light-emitting layer 13 may be composed of a single or multiple quantum well ((multiple) quantum well) structure. The light-emitting control layer 14 is located above the light-emitting layer 13 and forms a light-emitting opening area 15. The light emitted by the light-emitting layer 13 can be emitted through the light-emitting opening area 15.

Furthermore, in the following embodiments of the present invention, the semiconductor epitaxial structure 10 includes a first semiconductor structure 11, a second semiconductor structure 12, a light-emitting layer 13, and a light-emitting control layer 14. The first semiconductor structure 11 and the second semiconductor structure 12 are respectively a Distributed Bragg Reflector (DBR) structure composed of a plurality of semiconductor material layers, and the first semiconductor structure 11 and the second semiconductor structure 12 have different polarities. For example, in one embodiment of the invention, the first semiconductor structures 11 are N-type semiconductor material layers, and the second semiconductor structures 12 are P-type semiconductor material layers, but the invention is not limited thereto.

The light-emitting layer 13 is located between the first semiconductor structure 11 and the second semiconductor structure 12, and the light-emitting control layer 14 is formed in the second semiconductor structure 12 adjacent to the light-emitting layer 13. The light-emitting control layer 14 is an oxide layer formed by using moisture or ion distribution for the P-type semiconductor material layer in the second semiconductor structure 12. The light-emitting opening area 15 has a radial length L1, and the radial length L1 can change with different design requirements. In addition, a bottom electrode (not shown) may be provided on the surface of one side of the first semiconductor structure 11.

The light-absorbing structure 20 is located on the semiconductor epitaxial structure 10. The light-absorbing structure 20 can form a hollow part 24, and the position of the hollow part 24 corresponds to the position of the light-emitting opening area 15 based on the light emission direction, so that the light from the light-emitting layer 13 can only be emitted directly through the hollow part 24. The hollow part 24 penetrates from the surface of one side of the light-absorbing structure 20 to the surface of the other opposite side, so that the semiconductor epitaxial structure 10 is partially exposed through the hollow part 24. The light absorbing structure 20 mainly has light absorption characteristics. Therefore, in terms of material selection, the energy gap of the light-absorbing structure 20 will be smaller than the luminescence energy gap of the semiconductor laser element 1. In one embodiment of the present invention, the light-absorbing structure 20 is made of gallium arsenide (GaAs) material, aluminum gallium arsenide (AlₓGa₁₋ₓAs) material, or aluminum gallium indium arsenide phosphorus material (AlₓIn_{y}Ga_{1-x-y}As₂P_{1-z}), but the present invention is not limited thereto.

In addition to the present invention, the light-absorbing structure 20 can be formed into a single-layer or a multiple-layer structure according to different design requirements, and the light-absorbing structure 20 can be selected to be conductive or non-conductive. For example, in this embodiment, the light-absorbing structure 20 includes a conductive first light-absorbing layer 21. The first light-absorbing layer 21 is conductive under the premise of using the aforementioned gallium arsenide material, aluminum gallium arsenide material, or aluminum gallium indium phosphorus material and undergoing doping or other treatments. However, the present invention is not limited thereto.

The transparent conductive layer 30 is formed on the semiconductor epitaxial structure 10 and the light-absorbing structure 20 to serve as an electrical conduction path. The transparent conductive layer 30 mainly includes a recessed window part 31 and an extension part 32. The recessed window part 31 is located in the hollow part 24 of the light-absorbing structure 20, and the recessed window part 31 forms a recessed structure that is concave toward the hollow part 24. The transparent conductive layer 30 covers and contacts the semiconductor epitaxial structure 10 through the recessed window part 31, so that the recessed window part 31 forms an ohmic contact with the semiconductor epitaxial structure 10. The position of the recessed window part 31 of the transparent conductive layer 30 is based on the light emission direction corresponding to the position of the light-emitting opening area 15 so that the light from the light-emitting layer 13 can be emitted directly through the recessed window part 31. The extension part 32 is connected to the recessed window part 31, and the extension part 32 covers and contacts the light-absorbing structure 20, wherein the extension part 32 and the light-absorbing structure 20 can selectively form an ohmic contact. The transparent conductive layer 30 mainly has light-transmitting properties and electrical conductivity. Therefore, in one embodiment of the present invention, the transparent conductive layer 30 is made of indium tin oxide (ITO) material or other conductive and light-transmitting materials. However, the present invention is not limited thereto. The portion of the recessed widow part 31 that contacts the semiconductor epitaxial structure 10 has a radial length L2, and the radial length L2 can change with different design requirements.

In one embodiment of the present invention, the thickness of the transparent conductive layer 30 is n*λ/4, wherein n is a positive integer and λ is the wavelength of light.

The electrode layer 40 is located on the transparent conductive layer 30. The electrode layer 40 can form an opening 41, and the position of the opening 41 corresponds to the position of the light-emitting opening area 15 based on the light emission direction so that the light emitted from the light-emitting layer 13 can directly pass through the opening 41. The opening 41 penetrates from the surface of one side of the electrode layer 40 to the surface of the other opposite side, so that the transparent conductive layer 30 is partially exposed through the opening 41. In terms of structural design, based on the light emission direction, the recessed window part 31 of the transparent conductive layer 30 is located within the opening 41 of the electrode layer 40. That is to say, the radial length of the opening 41 is greater than the radial length L2 of the recessed window part 31. Therefore, at least the entire recessed window part 31 will be exposed through the opening 41 to prevent the light emission path from being blocked. The electrode layer 40 is made of metal material, but the invention is not limited thereto.

In the present invention, by changing the radial length L1 of the light-emitting opening area 15 and the radial length L2 of the recessed window part 31, the light-emitting mode provided by the semiconductor laser element of the present invention can be controlled. For example, when the radial length L1 of the light-emitting opening area 15 is greater than the radial length L2 of the recessed window part 31, the semiconductor laser element 1 of the present invention can provide single-mode light emission; and when the radial length of the light-emitting opening area 15 L1 is not greater than the radial length L2 of the recessed window part 31, and the semiconductor laser element 1 of the present invention can provide multi-mode light emission.

The following describes the operating principle and efficacy of the semiconductor laser element 1 of the present invention regarding the aforementioned first embodiment. In this embodiment, when power is supplied to the electrode layer 40, current will flow from the electrode layer 40 to the transparent conductive layer 30, so that the transparent conductive layer 30 cooperates with the electrode layer 40 to form a large-scale electrode structure. In a state where the recessed window part 31 of the transparent conductive layer 30 forms an ohmic contact with the semiconductor epitaxial structure 10 and the extension part 32 of the transparent conductive layer 30 forms an ohmic contact with the light absorbing structure 20, current can directly flow through the semiconductor epitaxial structure 10 from the recessed window part 31 and pass through the light-emitting opening area 15 to reach the light-emitting area 13, or the current can flow through the light-absorbing structure 20, the semiconductor epitaxial structure 10 and the light-emitting opening area 15 sequentially from the extension part 32 and then reach the light-emitting area 13, so that the current can be evenly distributed in the light-emitting opening area 15. The light-emitting area 13 can emit light after receiving current, and the light will be restricted by the light-emitting opening area 15 and emitted in a direction perpendicular to the surface of the light-emitting area 13. Due to the structural configuration, the light-emitting opening area 15 will be aligned with the recessed window part 31 of the transparent conductive layer 30 and the opening 41 of the electrode layer 40 based on the light emission direction, so that the light can concentrate through the light-emitting opening area 15 and the first semiconductor structure 11, the recessed window part 31, the hollow portion 24, and the opening 41 of the light absorbing structure 20 are emitted to the outside of the component, and the light in other directions will be blocked and absorbed by the light absorbing structure 20.

Furthermore, in this embodiment, assuming that the extended part 32 of the transparent conductive layer 30 and the light-absorbing structure 20 do not form ohmic contact (that is, the first light-absorbing layer 21 is not conductive), the current can only flow directly through the recessed window part 31 to the semiconductor epitaxial structure 10 and passes through the light-emitting opening area 15 to reach the light-emitting area 13. At this time, the current can be concentrated and flowed out from the recessed window part 31 and evenly distributed between the radial length L1 of the light-emitting opening area 15 and the radial length L2 of the recessed window part 31. Accordingly, the luminous efficiency of the semiconductor laser element 1 of the present invention can be further improved.

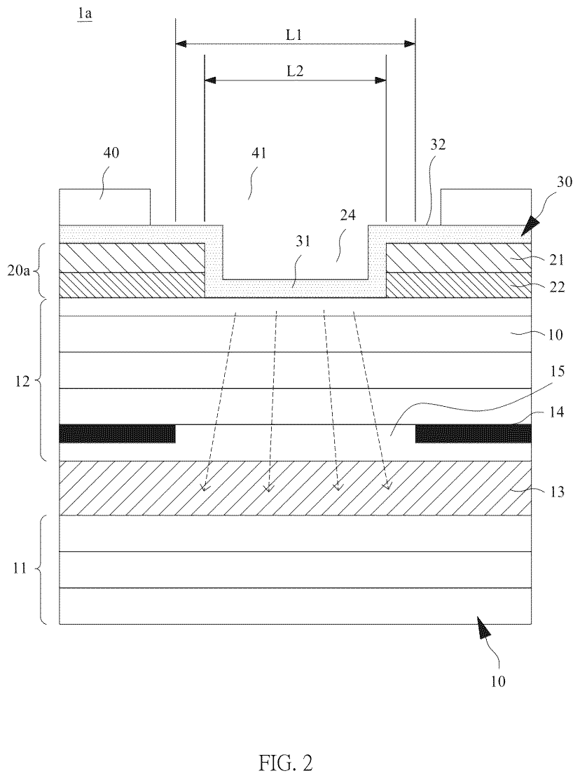

Please refer to FIG. 2, which is a schematic diagram of a second embodiment of the semiconductor laser element of the present invention. This embodiment is a variation of the aforementioned first embodiment and mainly adopts different types of light-absorbing structures. As shown in FIG. 2, in this embodiment, the light absorption structure 20a of the semiconductor laser element 1a includes a first light-absorbing layer 21 and a second light-absorbing layer 22. The first light-absorbing layer 21 is stacked on the second light-absorbing layer 22, and the second light-absorbing layer 22 and the first light-absorbing layer 21 have opposite polarities; for example, the first light-absorbing layer 21 is an N-type semiconductor material layer, the second light absorbing layer 22 is a P-type semiconductor material layer. The first light-absorbing layer 21 and the second light-absorbing layer 22 can also be formed using the aforementioned gallium arsenide material, aluminum gallium arsenide material, or aluminum gallium indium arsenide phosphorus material through doping or other processing. Since the second light-absorbing layer 22 and the first light-absorbing layer 21 have opposite polarities, a P-N interface is formed between them, so that the entire surface of the light-absorbing structure 20 a forms an ohmic contact with the transparent conductive layer 30 in the horizontal direction, but the energy barrier formed from the vertical interface cannot conduct current, so that the current cannot longitudinally pass through the light-absorbing structure 20a from the transparent conductive layer 30, and can only directly flow through the semiconductor epitaxial structure 10 through the recessed window part 31 and pass through the light-emitting opening area 15 to reach the light-emitting area 13. Accordingly, this embodiment can also improve the luminous efficiency of the semiconductor laser element 1a of the present invention.

In this embodiment, in addition to the foregoing method, the second light-absorbing layer can also be directly made of insulating material or made to have insulating properties (for example, doped with Fe element, etc.). Since the second light-absorbing layer 22 is electrically insulated, the entire surface of the light-absorbing structure 20 forms an ohmic contact with the transparent conductive layer 30 in the horizontal direction. However, the second light-absorbing layer 22 is electrically insulated, so that the current can only be directly passed through the window portion 31, flow through the semiconductor epitaxial structure 10 and pass through the light-emitting opening area 15 to reach the light-emitting area 13.

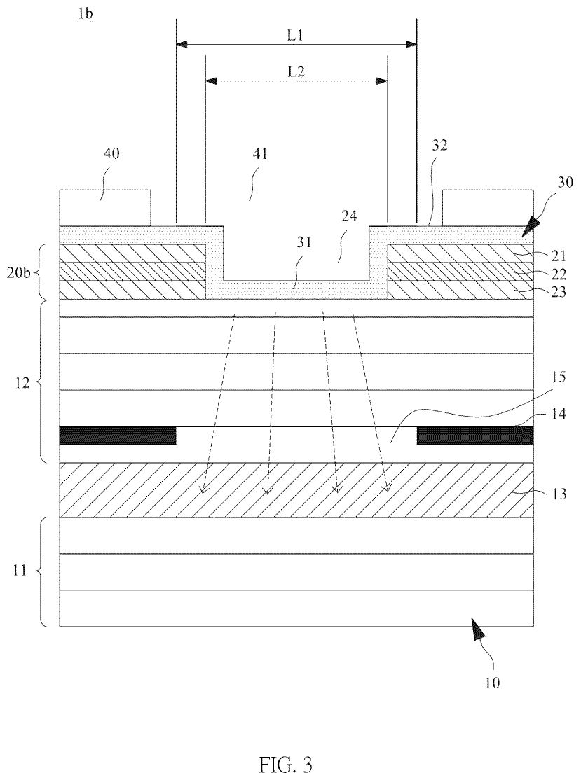

Please refer to FIG. 3 which is a schematic diagram of a third embodiment of the semiconductor laser element of the present invention. This embodiment is a variation of the aforementioned first embodiment and mainly adopts different types of light-absorbing structures. As shown in FIG. 3, in this embodiment, the light-absorbing structure 20b of the semiconductor laser element 1b of the present invention includes a first light-absorbing layer 21, a second light-absorbing layer 22 and a third light-absorbing layer 23. The first light-absorbing layer 21 is stacked on the second light-absorbing layer 22, and the second light-absorbing layer 22 and the first light-absorbing layer 21 have opposite polarities; the second light-absorbing layer 22 is stacked on the third light-absorbing layer 23, and the third light absorbing layer 23 and the first light absorbing layer 21 have the same polarity. For example, when the first light-absorbing layer 21 is an N-type semiconductor material layer, the second light-absorbing layer 22 is a P-type semiconductor material layer, and the third light-absorbing layer 23 is an N-type semiconductor material layer. The first light absorption layer 21, the second light absorbing layer 22, and the third light absorbing layer 23 can also be formed using the aforementioned gallium arsenide material, aluminum gallium arsenide material, or aluminum gallium indium arsenide phosphorus material through doping or other treatments. Since the second light-absorbing layer 22 and the first light-absorbing layer 21 have opposite polarities, and the third light-absorbing layer 23 and the second light-absorbing layer 22 have opposite polarities, it is further ensured that current cannot pass through the light-absorbing structure 20b from the transparent conductive layer 30, and can only directly flow through the semiconductor epitaxial structure 10 through the window portion 31 and pass through the light-emitting opening area 15 to reach the light-emitting area 13. Accordingly, this embodiment can also improve the luminous efficiency of the semiconductor laser element 1b of the present invention.

The above embodiments are essentially provided for auxiliary explanation and are not intended to limit the embodiments of the claimed subject matter or their applications or uses. Furthermore, even though at least one illustrative embodiment has been presented in the foregoing embodiments, it should be understood that there can still be numerous variations within the scope of the invention. It should also be understood that the embodiments described herein are not intended to limit the scope, application, or configuration of the claimed subject matter in any way. On the contrary, the foregoing embodiments will provide a convenient guide for those skilled in the art to implement one or more embodiments of the claimed subject matter. Moreover, various changes in the functionality and arrangement of components can be made within the scope defined by the claims, and the claims encompass known equivalents and foreseeable equivalents at the time of filing this patent application.

1. A semiconductor laser element, comprising:
a semiconductor epitaxial structure including a light-emitting layer and a light-emitting control layer, wherein the light-emitting control layer is located above the light-emitting layer and forms a light-emitting opening area;
a light-absorbing structure being located on the semiconductor epitaxial structure and forms a hollow part to expose the semiconductor epitaxial structure, wherein a band gap of the light-absorbing structure is smaller than the light-emitting band gap;
a transparent conductive layer including a recessed window part and an extension part, the recessed window part is located in the hollow part and covers the semiconductor epitaxial structure, and the extension part covers the light-absorbing structure; and
an electrode layer being located on the transparent conductive layer and forms an opening to expose the transparent conductive layer, wherein the recessed window part is located in the opening;
wherein a position of the recessed window part corresponds to a position of the light-emitting opening area based on the light-emitting direction.

2. The semiconductor laser element claimed in claim 1, wherein the light-absorbing structure includes a first light-absorbing layer that is electrically conductive.

3. The semiconductor laser element claimed in claim 2, wherein the light absorbing structure further includes a second light absorbing layer, the first light absorbing layer is stacked on the second light absorbing layer, and the second light absorbing layer and the first light absorbing layer has opposite polarities.

4. The semiconductor laser element claimed in claim 2, wherein the light absorbing structure further includes a second light absorbing layer, the first light absorbing layer is stacked on the second light absorbing layer, and the second light absorbing layer has insulating properties.

5. The semiconductor laser element claimed in claim 2, wherein the light absorbing structure further includes a second light absorbing layer and a third light absorbing layer, the first light absorbing layer is stacked on the second light absorbing layer, and the second light absorbing layer is stacked on the third light absorbing layer; wherein the second light absorbing layer and the first light absorbing layer have opposite polarities, and the third light absorbing layer and the first light absorbing layer have the same polarity.

6. The semiconductor laser element claimed in claim 1, wherein a radial length of the opening is greater than the radial length of the recessed window part.

7. The semiconductor laser element claimed in claim 1, wherein the radial length of the light-emitting opening area is greater than the radial length of the recessed window part so that the semiconductor laser element provides single-mode light emission.

8. The semiconductor laser element claimed in claim 1, wherein the radial length of the light-emitting opening area is no greater than the radial length of the recessed window part so that the semiconductor laser element provides multi-mode light emission.

9. The semiconductor laser element claimed in claim 1, wherein the thickness of the transparent conductive layer is n*λ/4.

10. The semiconductor laser element claimed in claim 1, wherein the recessed window part forms an ohmic contact with the semiconductor epitaxial structure.

11. The semiconductor laser element claimed in claim 1, wherein the light absorbing structure is made of gallium arsenide material, aluminum gallium arsenide material, or aluminum gallium indium arsenide phosphorus material.

12. The semiconductor laser element as claimed in claim 1, wherein the semiconductor epitaxial structure further includes:
a first semiconductor structure; and
a second semiconductor structure, wherein the light-emitting layer is located between the first semiconductor structure and the second semiconductor structure, and the light-emitting control layer is formed in the second semiconductor structure adjacent to the light-emitting layer.
